(19) United States
(12) Patent Application Publication
(10) Pub. No.: US 2011/0074383 A1
(43) Pub. Date: Mar. 31, 2011

(54) Assemblies and Methods for Sensing Current Through Semiconductor Device Leads

(75) Inventors: Bruce A. Frederick, Plymouth, MN (US); Kwong Kei Chin, Fremont, CA (US)

(73) Assignee: Astec International Limited, Kowloon (HK)

(21) Appl. No.: 12/568,816

(22) Filed: Sep. 29, 2009

(51) Int. Cl. G01R 19/00

(52) U.S. Cl. 324/76.11

(57) ABSTRACT

Assemblies and methods for sensing current through semiconductor device leads are disclosed. One example method includes mounting a current sense assembly about a lead of a semiconductor device. The current sense assembly may include a carrier adapted to hold a current sensor in close proximity to a semiconductor device lead to sense current flowing in the lead. One example assembly for sensing current through a semiconductor device lead includes a carrier for mounting to the semiconductor device lead and a current sensor supported by the carrier. The carrier includes output terminals. The current sensor has leads electrically coupled to the output terminals. The current sensor is positioned to extend around at least a portion of the lead and provide a signal to the output terminals representing current flowing in the lead when the carrier is mounted to the lead.

### FIELD

The present disclosure relates to assemblies and methods for sensing current through one or more leads of a semiconductor device.

### BACKGROUND

This section provides background information related to the present disclosure which is not necessarily prior art.

Current sensors are commonly employed in electric circuits to measure (directly or indirectly) one or more flowing currents. For example, power converters often include current sensors to provide feedback information for use in controlling the power converter. Many current sensors include a transformer having a primary winding connected in the path of a current to be measured, and a secondary winding for providing a (typically reduced) signal indicating the level of current flowing in the current path.

### SUMMARY

This section provides a general summary of the disclosure, and is not a comprehensive disclosure of its full scope or all of its features.

According to one aspect of the present disclosure, an assembly for sensing current through a lead of a semiconductor device includes a carrier for mounting to the lead of the semiconductor device and a current sensor supported by the carrier. The carrier includes output terminals. The current sensor has leads electrically coupled to the output terminals. The current sensor is positioned to extend around at least a portion of the lead and provide a signal to the output terminals representing current flowing in the lead when the carrier is mounted to the lead.

According to another aspect of the present disclosure, an assembly includes a semiconductor device having a lead, a carrier including output terminals and a non-conductive sleeve for receiving the lead of the semiconductor device, and a current sensor supported by the carrier and having leads electrically coupled to the output terminals. The current sensor is positioned to extend around the lead of the semiconductor device and provide a signal to the output terminals representing current flowing in the lead of the semiconductor device.

According to yet another aspect of the present disclosure, a method includes mounting a current sense assembly about a lead of a semiconductor device.

According to still another aspect of the present disclosure, a carrier is disclosed. The carrier is adapted to hold a current sensor in close proximity to a semiconductor device lead to sense current flowing in the lead.

Further areas of applicability will become apparent from the description provided herein. It should be understood that various aspects of this disclosure may be implemented individually or in combination with one or more other aspects. It should also be understood that the description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a bottom perspective view of an assembly for sensing current through a semiconductor device lead according to one example embodiment of the present disclosure.

FIG. 2 is a top view of the assembly of FIG. 1.

FIG. 3 is a front perspective view of an integrated circuit assembly including the assembly of FIG. 1 according to another example embodiment.

FIG. 4 is a side elevational view of the assembly of FIG. 3.

FIG. 5 is a front elevational view of the assembly of FIG. 3.

Corresponding reference numerals indicate corresponding parts throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath”, “below”, “lower”, “above”, “upper” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

According to one aspect of the present disclosure, a method is provided for sensing current flow in a semiconductor device lead. The method includes mounting a current sense assembly about the lead of the semiconductor device. Additionally, the method may further include mounting the semiconductor device to a circuit board. In that event, the current sense assembly may be mounted about the lead before or after the semiconductor device is mounted to the circuit board. Further, the current sense assembly may be mounted about the lead on a same side of the circuit board as the integrated circuit or, alternatively, on an opposite side (e.g., after the integrated circuit has been mounted to the board with the lead extending through the board to the opposite side). The current sense assembly may also include an output for providing a signal representing current flowing through the semiconductor device lead. In that case, the method may further include electrically coupling the output of the current sense assembly to the circuit board.

In some embodiments, the current sense assembly includes a current sensor and a carrier adapted to hold the current sensor in close proximity to the semiconductor device lead to sense current flowing in the lead. The carrier may be further adapted for attachment to the lead, with the carrier supporting the current sensor on the lead. Additionally, the carrier may include a nonconductive material defining an opening. In that event, the current sense assembly may be mounted about the semiconductor device lead by inserting the lead through the carrier opening.

Employing the method described above may result in a number of advantages, which may include reducing the amount of circuit board space required for current sensing components, reducing the resistance and/or inductance of the current path for which current is sensed, reducing the number of solder connections, reducing noise and/or other advantages.

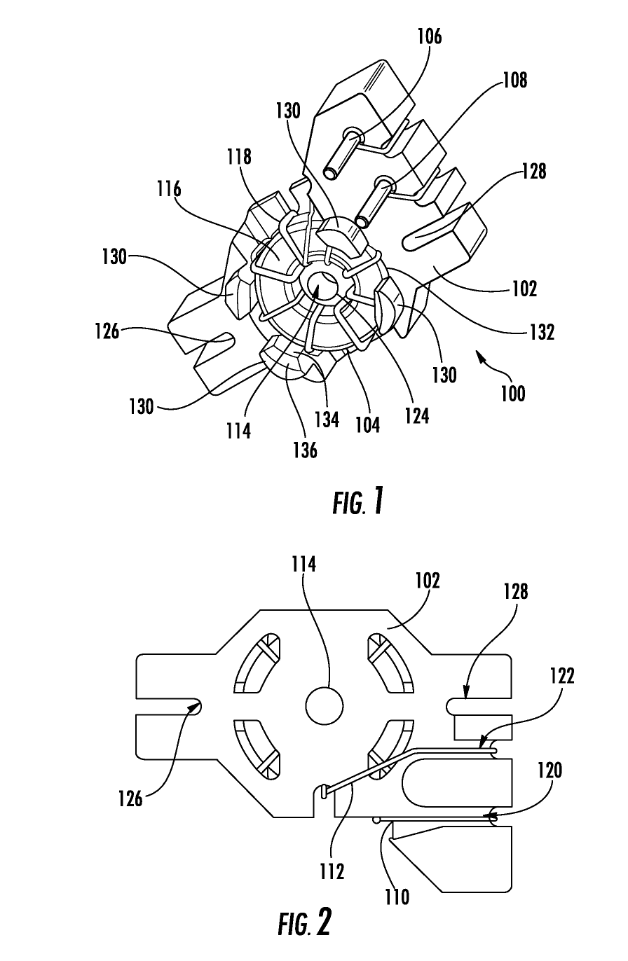

One example embodiment of a current sense assembly suitable for use in the method described above will now be described with reference to FIGS. 1-5. It should be understood, however, that the example embodiment is provided for illustrative purposes only, and that the method described above can be practiced with a variety of other current sense assemblies. Further, the current sense assembly described below with reference to FIGS. 1-5 may be usable in other methods.

As shown in FIG. 1, the example embodiment of a current sense assembly 100 includes a carrier 102 for mounting to the lead of a semiconductor device and a current sensor 104 supported by the carrier 102. The carrier 102 includes output terminals 106, 108. The current sensor 104 includes leads 110, 112 electrically coupled to the output terminals 106, 108, respectively. When the carrier 102 is mounted to the lead of a semiconductor device, the current sensor 104 is positioned to extend around at least a portion of the lead and provide a signal to the output terminals 106, 108 representing current flowing in the lead.

The carrier 102 includes an opening 114 for receiving the lead of the semiconductor device. In this particular embodiment, the current sensor 104 includes a magnetic core 116 surrounding the carrier opening 114. As shown, the magnetic core 116 has a generally toroidal shape. Alternatively, current sensors having other core shapes may be employed. The magnetic core 116 is wrapped with a winding 118 having opposite ends (i.e., the leads 110, 112) coupled to the output terminals 106, 108. In this example, the leads 110, 112 are routed to the output terminals 106, 108 through U-shaped channels 120, 122 extending along the top and side of the carrier 102.

As shown in FIG. 1, the carrier 102 further includes a nonconductive sleeve 124 that defines the opening 114. In this particular embodiment, the sleeve 124 is configured to contact and form a friction fit with the lead when the carrier 102 is mounted about the lead of the semiconductor device. The nonconductive sleeve 124 is positioned to inhibit contact between the lead and the current sensor 104 to prevent electrical shorts and/or protect the current sensor 104 and/or the lead. For example, if the current sensor includes a coated winding wire, the nonconductive sleeve may protect the wire coating from one or more edges of a metallic lead. In other embodiments, the carrier may not contact a lead of the semiconductor device, in which case the sleeve 124 may not be used.

The carrier 102 shown in FIGS. 1 and 2 may be formed from a nonconductive nylon material such as DuPont Zytel 101 HSL. Alternatively, other types of nonconductive materials may be employed. Further, the entire carrier 102 (except for the output terminals 106, 108) or only portion(s) thereof may be formed from a nonconductive material. Depending on the type of material(s) employed, the carrier 102 may be formed by injection molding or any other suitable process.

As shown in FIG. 2, the carrier 102 includes slots 126, 128 for receiving additional leads of the semiconductor device to inhibit rotational movement of the assembly 100 relative to the semiconductor device. Other carrier embodiments may include a different number of slots, e.g., one, three, none, etc. The number of slots may depend on the number of leads included in the semiconductor device and/or whether other means are provided for inhibiting rotation of the carrier 102 relative to the lead. Alternatively, contact between a carrier and a semiconductor device may be avoided altogether.

Referring again to FIG. 1, the carrier 102 includes a plurality of tabs 130 positioned about and contacting an outer periphery of the current sensor 104. The tabs 130 retain the current sensor 104 at least partially within a region 132 defined by the carrier 102. In the embodiment shown, each tab 130 includes an undercut surface 134 for retaining the current sensor 104 and a ramp surface 136 for receiving and guiding the current sensor 104 into the region 132 of the carrier 102. A different number of tabs and/or other provisions (such as fasteners, adhesives, covers, etc.) may be employed in other embodiments for securing a current sensor to a carrier.

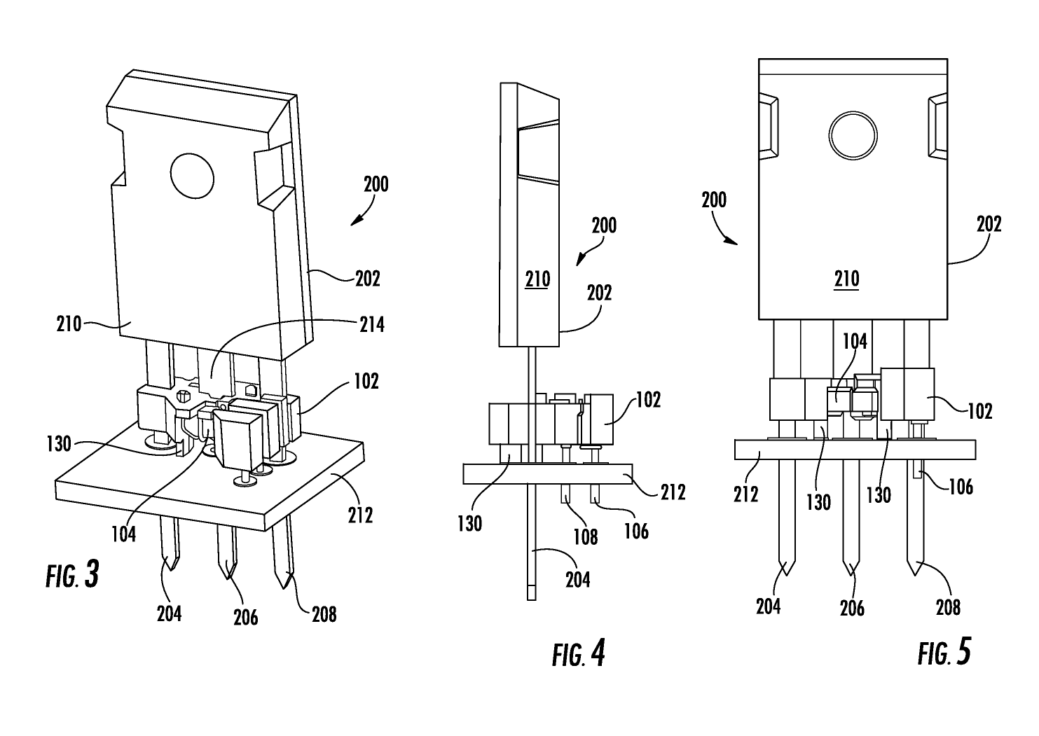

FIGS. 3-5 illustrate an integrated circuit assembly 200 according to another example embodiment. The assembly 200 includes the assembly 100 of FIGS. 1-2 mounted to a semiconductor device 202. As shown, the semiconductor device 202 includes three leads 204, 206, 208 and a body 210. Lead 206 is received through the magnetic core of current sensor 104 and forms a friction fit with the sleeve 124. Leads 204, 208 are received in the slots 126, 128, respectively, to inhibit rotational movement of the assembly 100 about the lead 206. As shown in FIGS. 3-5, the assembly 200 includes a circuit board 212. The assembly 100 and the semiconductor device 202 are positioned on the same side (i.e., the top) of the circuit board 212. Alternatively, the current sense assembly may be positioned on a different side (i.e., the bottom) of the circuit board 212 than the semiconductor device 210. Further, while the current sensor 104 is adapted to extend completely around the lead of a semiconductor device, it could alternatively include a slot or other provisions that permit the sensor to be positioned around at least a portion of the lead without requiring insertion of the lead through an opening. In this manner, the sensor could be positioned to extend around only a portion of the lead, on the same side of the circuit board as the body of the semiconductor device, after the semiconductor device is coupled (e.g., soldered) to the circuit board.

As shown, a footprint of the semiconductor device 202 is increased only minimally, while incorporating the assembly 100 for sensing current through the lead 206 of semiconductor device 202.

When the lead 204 is received in the opening 114, the magnetic core 116, the winding 118, and the lead 204 behave substantially as a transformer. In particular, the lead 204 functions as the primary winding of the transformer for energizing the core 116. Thus, when current flows through the lead 204, current is induced in winding 118, resulting in a voltage across the output terminals 106, 108. This voltage represents the current flowing in the lead 204 of the semiconductor device 202. As shown in FIGS. 3-5, the output terminals 106, 108 of the carrier 102 are electrically coupled to the circuit board 212 for providing the voltage signal representing current flowing through the lead 206 of the semiconductor device 202.

Because current is sensed through the lead 206 of the semiconductor device 202 (i.e., an inline current path), the assembly 200 reduces interconnection inductance by about 4 nH (as compared to an assembly employing a prior art current transformer.

As shown in FIGS. 4-5, the carrier includes tabs 130 to inhibit contact between the current sensor 104 and the circuit board 212. In this example embodiment, the tabs 130 retain the current sensor between the tabs and inhibit contact between the current sensor and the circuit board. Further, the carrier 102 abuts a wider portion 214 of the lead 206 to position the carrier 102 on the lead 206 as desired (which may include inhibiting contact between the body 210 of the semiconductor device 202 and the current sensor 104).

In the example assembly 200 shown in FIGS. 3-5, the semiconductor device 202 is a power MOSFET with the drain lead 206 extending through the opening 124 of the current sense assembly 100. It should be understood, however, that the teachings of this disclosure may be used with a wide variety of other semiconductor devices, including those that do not employ a through-hole packaging arrangement.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

What is claimed:

1. An assembly for sensing current through a lead of a semiconductor device, the assembly comprising:
a carrier for mounting to the lead of the semiconductor device, the carrier including output terminals; and
a current sensor supported by the carrier and having leads electrically coupled to the output terminals, the current sensor positioned to extend around at least a portion of the lead and provide a signal to the output terminals representing current flowing in the lead when the carrier is mounted to the lead.

2. The assembly of claim 1 wherein the carrier includes an opening for receiving the lead of the semiconductor device.

3. The assembly of claim 2 wherein the current sensor includes a toroidal magnetic core substantially surrounding the carrier opening.

4. The assembly of claim 2 wherein the carrier includes a nonconductive sleeve defining said opening and disposed to inhibit contact between the lead and the current sensor.

5. The assembly of claim 1 wherein the carrier defines a slot for receiving another lead of the semiconductor device to inhibit rotational movement of the assembly relative to the semiconductor device.

6. The assembly of claim 1 wherein the carrier includes a plurality of tabs positioned about and contacting a perimeter of the current sensor to retain the current sensor in contact with the carrier.

7. A power converter including a semiconductor device having leads and the assembly of claim 1 mounted to at least one of the leads of the semiconductor device.

8. An assembly comprising:
a semiconductor device having a lead;
a carrier including output terminals and a non-conductive sleeve for receiving the lead of the semiconductor device; and
a current sensor supported by the carrier and having leads electrically coupled to the output terminals, the current sensor positioned to extend around the lead of the semiconductor device and provide a signal to the output terminals representing current flowing in the lead of the semiconductor device.

9. The assembly of claim 8 wherein the carrier includes a nonconductive nylon material.

10. The assembly of claim 8 wherein the carrier includes a plurality of tabs configured to inhibit contact between the current sensor and a circuit board when the assembly is mounted to the circuit board.

11. The assembly of claim 8 wherein the carrier defines two slots on opposite sides of the non-conductive sleeve, and wherein the semiconductor device includes at least two other leads positioned in the slots to inhibit rotation of the carrier relative to the semiconductor device.

12. A power supply including a circuit board and the assembly of claim 8 wherein the carrier output terminals are coupled to the circuit board.

13. A method comprising mounting a current sense assembly about a lead of a semiconductor device.

14. The method of claim 13 further comprising mounting the semiconductor device to a circuit board.

15. The method of claim 14 wherein mounting the lead includes mounting the semiconductor device to the circuit board after mounting the current sense assembly about the lead.

16. The method of claim 14 wherein mounting the current sense assembly includes mounting the current sense assembly to the lead on a same side of the circuit board as the semiconductor device.

17. The method of claim 16 wherein mounting the lead includes mounting the lead to the circuit board after mounting the current sense assembly about the lead.

18. The method of claim 14 wherein the current sense assembly includes an output for providing a signal representing current flowing through the lead of the semiconductor device, the method further comprising electrically coupling the output of the current sense assembly to the circuit board.

19. The method of claim 14 wherein the current sense assembly includes a current sensor and a carrier for supporting the current sensor.

20. The method of claim 19 wherein the carrier includes a nonconductive material defining an opening, wherein the current sensor extends around at least a portion of the opening, and wherein mounting the current sense assembly includes inserting the lead of the semiconductor device through the carrier opening.
